(19) United States
(12) Patent Application Publication
(10) Pub. No.: US 2011/0156929 A1
(43) Pub. Date: Jun. 30, 2011

(54) BUTTON FOR INPUT INTERFACE, INPUT INTERFACE AND PORTABLE TERMINAL

(76) Inventor: Kazutaka Sasamoto, Saitama (JP)

(21) Appl. No.: 13/061,295

(22) PCT Filed: Oct. 27, 2008
(86) PCT No.: PCT/JP2008/069429

§ 371 Date: Feb. 28, 2011

(51) Int. Cl. H03M 11/00

(52) U.S. Cl. 341/22

(57) ABSTRACT

The present invention provides a button for an input interface, and an input interface and a portable terminal thereof, which make visibility of an indicated character high, and make it easy to detect a boundary with the tactile sensation.

A button, which is used for an input interface of a portable terminal and which is stuck fixedly to a base sheet adjacently to at least one other button, is characterized in that a thin wall part, which is positioned lower than a key top part, is formed on at least one peripheral side adjacent to the other button and in that a character, which is printed on the base sheet or a surface stuck fixedly to the base sheet, is made visible by penetrating through the key top part and the thin wall part.

### TECHNICAL FIELD

The present invention relates to an input button which is applied to a portable terminal, and particularly relates to structure of a button which makes it possible to secure an area for installing each button, and in parallel to recognize a boundary between two adjacent buttons easily.

### BACKGROUND ART

A portable terminal such as a cellular phone, PDA (Personal. Digital Assistant), an electronic dictionary, a pocket calculator, a laptop computer and a remote control unit of an electronic appliance is equipped with an operating unit which generally includes a plurality of buttons.

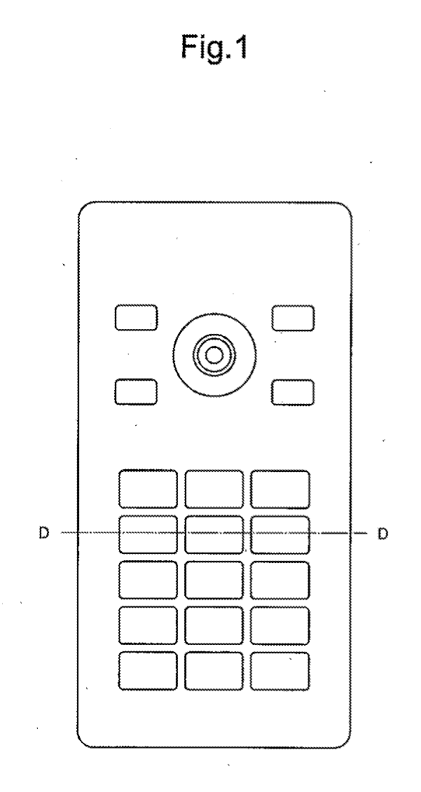

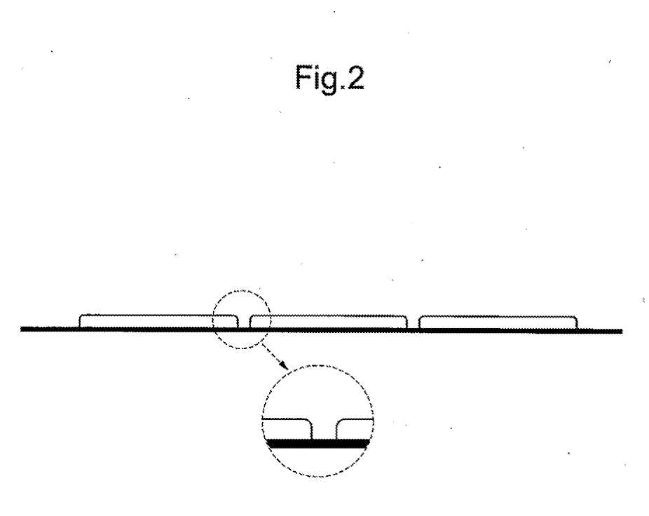

In the case of structure that an interval between the buttons is long as shown in FIG. 1 and FIG. 2, there exists a crosspiece between two buttons. Therefore, it is easy to recognize a boundary between two adjacent buttons by a fingertip (in other word, with the tactile sensation). However, in the case of a portable terminal which has limitation in size, an area for installing the operating unit is limited. In other words, if the interval between the buttons is made long, it is necessary to make size of each button small. In the case that each button becomes small, a character which is indicated on the button also becomes small. As a result, operability becomes degraded and visibility of the character, which is indicated on the button, also becomes degraded.

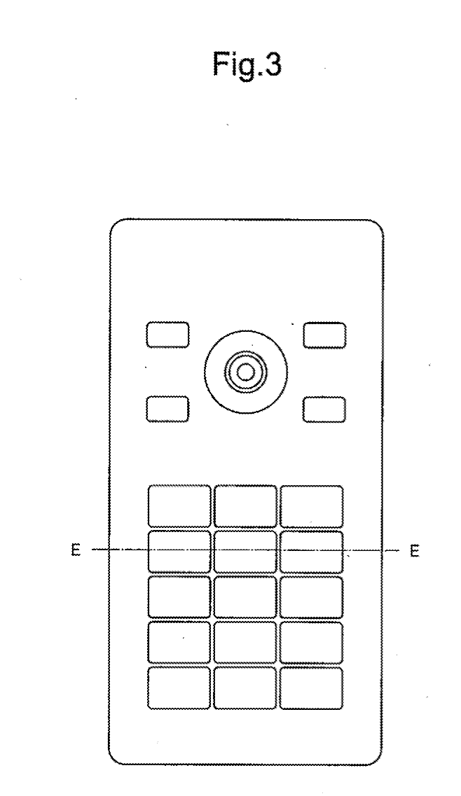

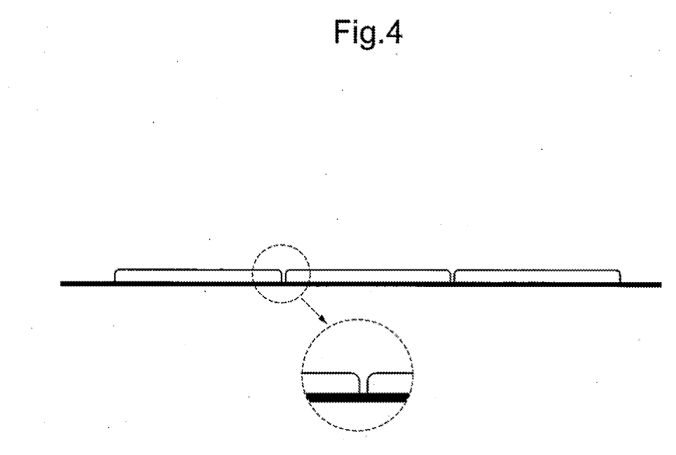

On the other hand, if the interval between the buttons is made short as shown in FIG. 3 and FIG. 4, it is possible to make size of each button large and consequently, it is also possible to make the character, which is indicated on the button, large. As a result, visibility becomes improved. However, since there does not exist the crosspiece between the buttons, it is difficult to recognize the boundary between the adjacent buttons with the tactile sensation.

As an invention related to structure of a button which is used in an electronic apparatus, “key top and manufacturing method thereof”, which is disclosed in patent document 1, is exemplified.

According to the invention disclosed in the patent document 1, an outside key top element which is arranged at a periphery of the key top, and an inside key top element which is arranged at the center of the key top are formed separately, and these elements are combined to be fixed together. As a result, a combined design surface is formed on a surface of the key top.
Patent document 1: Japanese Patent Application Laid-Open No. 2007-179952

### DISCLOSURE OF THE INVENTION

### Problem to be Solved by the Invention

According to the invention disclosed in the patent document 1, the outside key top element and the inside key top element are piled up at the periphery of the key top to be stuck fixedly together. Therefore, if these elements are stuck fixedly with enough strength, thickness of the key top becomes increasing. As a result, it is difficult to meet market needs of making a terminal thin.

Moreover, since an area for sticking fixedly the key top elements together is required at the periphery of the key top, the area causes disturbance to securing the key top area.

Moreover, since the combined design surface is formed on the surface of the key top, it is necessary to decorate the outside key top element and the inside key top element differently each other, according to the invention disclosed in the patent document 1.

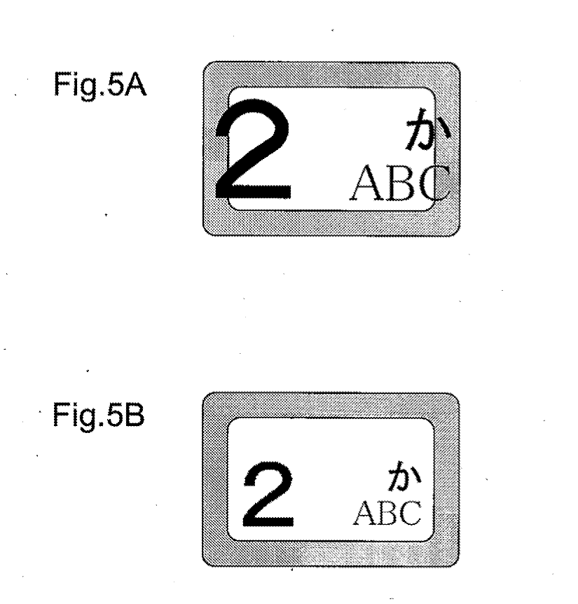

In the case that a character is indicated on the whole surface of the key top on the basis of the structure, it is necessary to indicate the character in a state that the character extends over the outside key top element and the inside key top element as shown in FIG. 5(a). However, in the case that the character is indicated in a state that the character extends over the outside key top element and the inside key top element, visibility of the character becomes degraded, since the outside key top element and the inside key top element are decorated differently each other. On the other hand, in the case that the character is indicated only on the inside key top element as shown in FIG. 5(b), size of the character becomes small and consequently, visibility of the character also becomes degraded.

The invention is conceived in consideration of the problem. An object of the present invention is to provide a button for an input interface, an input interface and a portable terminal thereof, which can make an indicated character visible highly and can detect a boundary area easily with the tactile sensation.

### Means for Solving the Problem

In order to achieve the above-mentioned object, the present invention provides a button, which is for an input interface of a portable terminal and which is stuck fixedly to a base sheet adjacently to at least one other button, characterized in that a thin wall part, which is positioned lower than a key top part, is formed on at least one peripheral side adjacent to the other button and that a character, which is printed on the base sheet or a surface stuck fixedly to the base sheet, is made visible by penetrating through the key top part and the thin wall part, as a first exemplary embodiment.

Moreover, in order to achieve the above-mentioned object, the present invention provides an input interface which is equipped with the button for the input interface according to the first exemplary embodiment of the present invention, as a second exemplary embodiment.

Moreover, in order to achieve the above-mentioned object, the present invention provides a portable terminal which is equipped with the input interface according to the second exemplary embodiment of the present invention, as a third exemplary embodiment.

### Effect of the Invention

According to the present invention, it is possible to provide the button for the input interface, and the input interface and the portable terminal thereof, which make visibility of the indicated character high, and make it easy to detect the boundary with the tactile sensation.

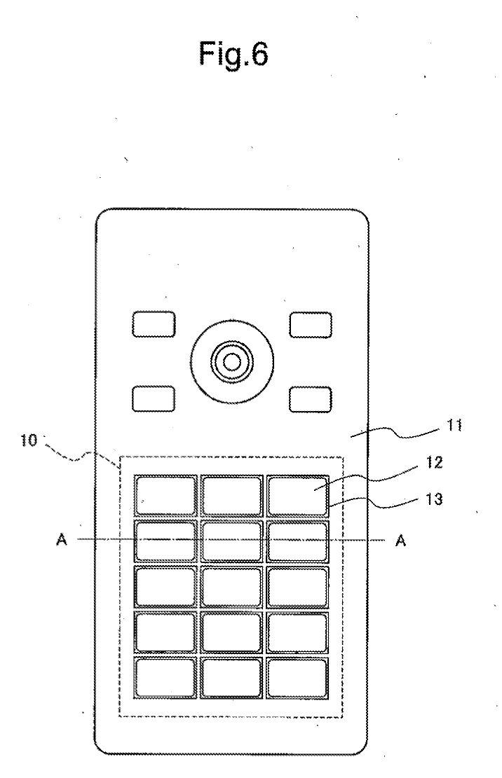

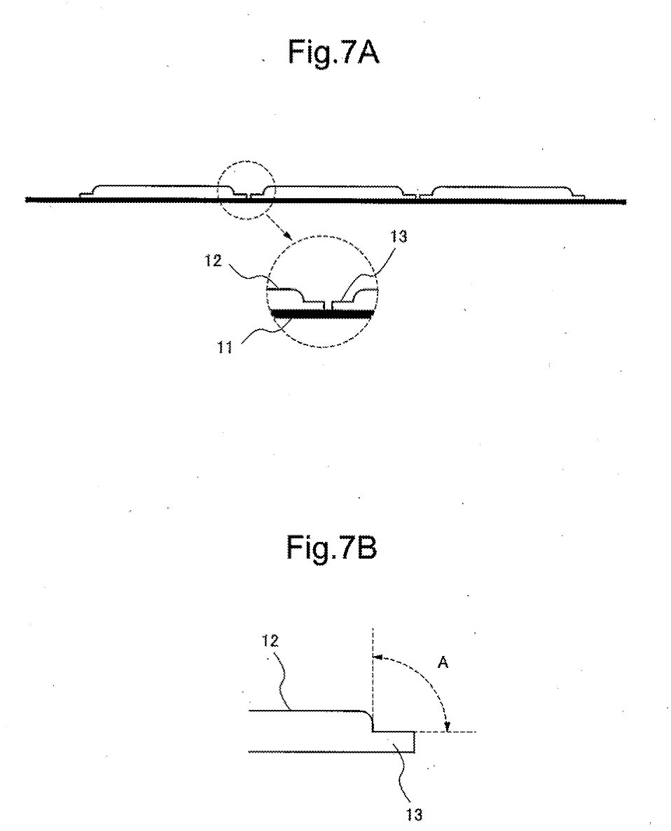

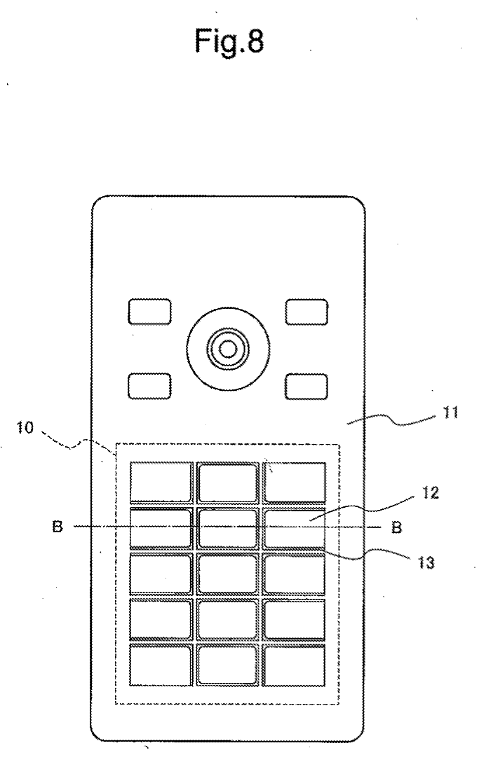

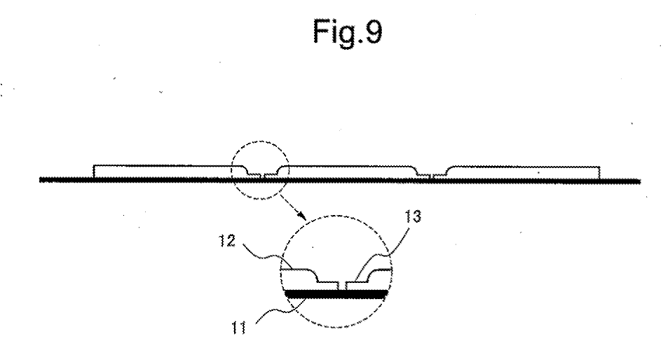

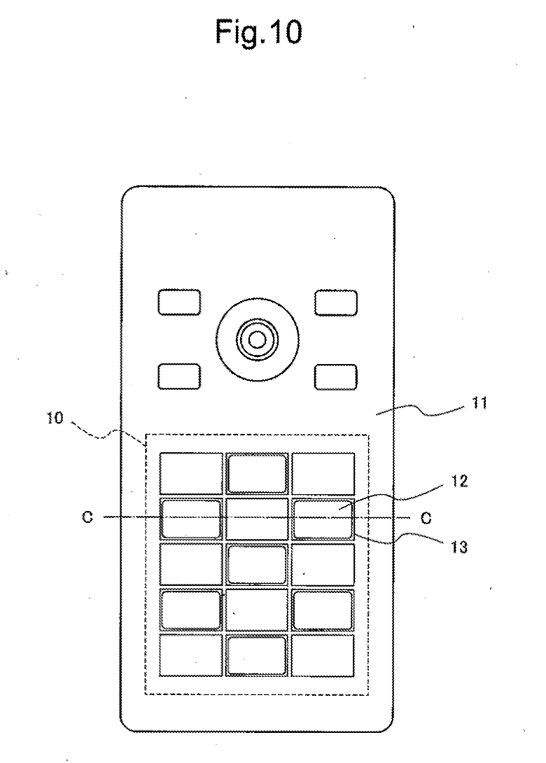

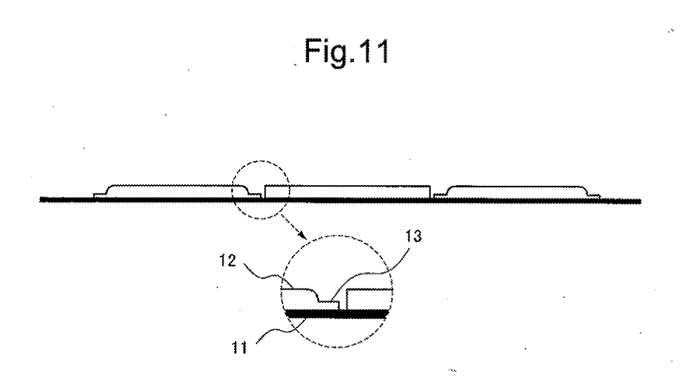

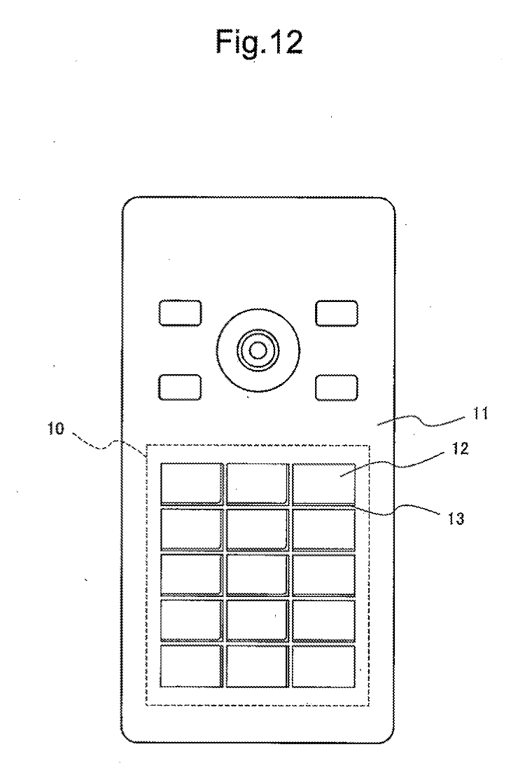

### BRIEF DESCRIPTION OF THE DRAWINGS

[FIG. 1] shows structure of a button related to the present invention.

[FIG. 2] is a cross section diagram taken along D-D line in the diagram which shows the structure of the button related to the present invention.

[FIG. 3] shows structure of a button related to the present invention.

[FIG. 4] is a cross section diagram taken along E-E line in the diagram which shows the structure of the button related to the present invention.

[FIG. 5] shows a state that a character is indicated on a key top according to the invention disclosed in patent document 1.

[FIG. 6] shows structure of a button according to a first preferred exemplary embodiment of the present invention.

[FIG. 7] is a cross section diagram taken along A-A line in the diagram which shows the structure of the button according to the first exemplary embodiment.

[FIG. 8] shows structure of a button according to a second preferred exemplary embodiment of the present invention.

[FIG. 9] is a cross section diagram taken along B-B line in the diagram which shows the structure of the button according to the second exemplary embodiment.

[FIG. 10] shows structure of a button according to a third preferred exemplary embodiment of the present invention.

[FIG. 11] is a cross section diagram taken along C-C line in the diagram which shows the structure of the button according to the third exemplary embodiment.

[FIG. 12] shows structure of a button according to the third exemplary embodiment.

### DESCRIPTION OF THE CODES

10 Operating part
11 Base sheet
12 Key top part
13 Thin wall part

### BEST MODE TO CARRY OUT THE INVENTION

### A First Exemplary Embodiment

A first preferred exemplary embodiment according to the present invention will be described in the following. FIG. 6 shows structure of a button according to the exemplary embodiment.

An operating part 10, which includes a plurality of buttons, is arranged on a base sheet 11. Referring to the structure of the button according to the exemplary embodiment, an interval between the buttons is short as shown in FIG. 7 (a), similarly to structure shown in FIG. 2. A thin walled part 13, which is arranged at a periphery of the button, is positioned lower than a key top part 12 which is arranged at a center of the button. Each button is made of clear resin and a character which indicates an assigned function or the like is printed on a back side surface. Therefore, the character is made visible by penetrating through the button.

Width of the thin wall part 13 and difference in height between the thin wall part 13 and the key top part 12 are satisfactory if existence of thin wall part 13 can be recognized with the tactile sensation. That is, width of the thin wall part 13 and difference in height between the thin wall part 13 and the key top part 12 are not limited to the specific value. Moreover, while an angle of the key top part 12 to the thin wall part 13 (angle A in FIG. 7 (b)) may have any value, it is preferable that the angle is almost right.

As shown in FIG. 7 (a), since the thin wall parts 13 of two buttons are adjacent each other at the boundary between two buttons adjacent each other, the thin wall parts 13 play the same role as one of a crosspiece. As a result, the boundary can be recognized easily with the tactile sensation. That is, since a three-dimensional step is formed by existence of the thin wall part 13, it is possible to recognize the boundary between the buttons even by a fingertip.

In the case that a character is printed on a front surface of the button, the character has to be printed within an area where the key top part 12 occupies. However, since a character is printed on the back surface of the button according to the exemplary embodiment, the character can be printed not only in the area where the key top 12 occupies but also in an area where the thin wall part 13 occupies. Therefore, if a character which is printed on the back surface has the same size as a character which is printed on the front surface has, it is possible to indicate more characters on the button, and if the characters are the same in number, it is possible to indicate the larger size character than the character printed on the front surface.

As mentioned above, since the step is formed by the thin wall part according to the structure of the button of the exemplary embodiment, it is possible to recognize easily the boundary between the buttons with the tactile sensation of the fingertip. Moreover, there is no case to degrade visibility of the character indicated on the button.

Furthermore, since all buttons are in the same shape, it is possible to reduce the production cost by common use of the component according to the exemplary embodiment.

### A Second Exemplary Embodiment

A second preferred exemplary embodiment according to the present invention will be described in the following. FIG. 8 and FIG. 9 show structure of buttons respectively according to the exemplary embodiment. The operating part 10, which includes a plurality of buttons, is arranged on the base sheet 11 similarly to the first exemplary embodiment.

According to the exemplary embodiment, the thin wall part 13 is formed only on a side adjacent to other button. Accordingly, in the case of a button which is not enclosed on all sides by the other button, it is possible to make the area of the key top part 12 wider than one of the first exemplary embodiment. For this reason, it is possible to improve operability of the operating part 10.

Moreover, since the step is formed by existence of the thin wall part 13 similarly to the first exemplary embodiment, it is possible to recognize easily the boundary between the buttons with the tactile sensation of the fingertip and there is no case to degrade visibility of the character indicated on the button.

### A Third Exemplary Embodiment

A third preferred exemplary embodiment according to the present invention will be described in the following. FIG. 10 and FIG. 11 show structure of buttons respectively according to the exemplary embodiment. The operating part 10, which includes a plurality of buttons, is arranged on the base sheet 11 similarly to the first exemplary embodiment.

According to the exemplary embodiment, the thin wall part 13 is formed on only one button out of the buttons which are adjacent each other, and the thin wall part 13 is not formed on the other button. Accordingly, in the case of a button which has no thin wall part 13, it is possible to make the area of the key top part 12 wider than one of the first exemplary embodiment. For this reason, it is possible to improve operability of the operating part 10.

Moreover, since the step is formed by existence of the thin wall part 13 similarly to the first exemplary embodiment, it is possible to recognize easily the boundary between the buttons with the tactile sensation of the fingertip and there is no case to degrade visibility of the character indicated on the button.

While the structure that two kinds of buttons, that is, the button with the thin wall part 13 and the button with no thin wall part 13, are used is exemplified, it may be preferable that the thin wall part 13 is formed only on a requisite side of each button as shown in FIG. 12.

Further, the above-mentioned embodiment is an example of the preferred embodiment of the present invention, and the present invention is not limited to the above-mentioned embodiment.

For example, it is possible to apply the present invention even in the case that the buttons are arranged diagonally in a vertical direction like a keyboard of a computer terminal, while the structure that the buttons are arranged at the right angle both in a vertical direction and in a horizontal direction is described according to each exemplary embodiment.

It is needless to say that the character, which is indicated on the button, may be printed not on the back side of the button but on the base sheet.

As mentioned above, it is possible to modify the present invention from various points of view.

This application is based upon and claims the benefit of priority from Japanese Patent Application No. 2008-256215, filed on Oct. 1, 2008, the disclosure of which is incorporated herein in its entirety by reference.

1. A button which is used for an input interface of a portable terminal and which is stuck fixedly to a base sheet adjacently to at least one other button, characterized in that:
a thin wall part of the button, which is positioned lower than a key top part of the button, is formed on at least one peripheral side adjacent to the other button; and
a character, which is printed on the base sheet or a surface stuck fixedly to the base sheet, is made visible by penetrating through the key top part and the thin wall part.

2. The button for the input interface according to claim 1, characterized in that:
an angle of the key top part to the thin wall part is almost right.

3. The button for the input interface according to claim 1 characterized in that:
the thin wall part is formed in a state of enclosing the key top part.

4. An input interface which is equipped with the button for the input interface according to claim 1.

5. The input interface which is equipped with the button for the input interface according to claim 1 characterized in that:
the thin wall part is formed on each button for the input interface at an area, through which two buttons are adjacent each other, in a state that the thin wall part is formed on only one button for the input interface out of two buttons.

6. The input interface of the portable terminal according to claim 4, characterized in that:
the buttons for the input interface are arranged in a matrix form in a vertical direction and in a horizontal direction.

7. A portable terminal which is equipped with the input interface of the portable terminal according to claim 4.
